(19) United States
(12) Patent Application Publication
(10) Pub. No.: US 2012/0112827 A1
(43) Pub. Date: May 10, 2012

(54) APPARATUS FOR SEMICONDUCTOR INTEGRATED CIRCUIT, DESIGN METHOD FOR SEMICONDUCTOR INTEGRATED CIRCUIT, AND SEMICONDUCTOR INTEGRATED CIRCUIT

(75) Inventor: Hiroaki Nishi, Kanagawa (JP)

(73) Assignee: KABUSHIKI KAISHA TOSHIBA, Tokyo (JP)

(21) Appl. No.: 13/231,693

(22) Filed: Sep. 13, 2011

(30) Foreign Application Priority Data
Nov. 10, 2010 (JP) 2010-252198

(51) Int. Cl. H01L 25/00; G06F 17/50

(52) U.S. Cl. 327/564; 716/102

(57) ABSTRACT

Design apparatuses according to the present embodiments each include a CDFG generator, a scheduler, a binder, a retention register selector, a control circuit generator, and an RTL description generator. The binder generates a data path circuit in which a hardware element is allocated to a CDFG after scheduling by the scheduler. The retention register selector detects, as a retention control step, one of the control steps which has a minimum number of latch bits from the CDFG after scheduling and selects, as a retention register, a register allocated to the detected retention control step. The control circuit generator generates a control circuit which performs an execution control of the data path circuit and causes a state to transition to the retention control step when a signal for power-off is enabled.

### CROSS-REFERENCE TO RELATED APPLICATION

This application is based upon and claims the benefit of priority from the prior Japanese Patent Application No. 2010-252198 filed on Nov. 10, 2010; the entire contents of which are incorporated herein by reference.

### FIELD

Embodiments of the present invention described herein relate generally to a design apparatus for a semiconductor integrated circuit, a design method for a semiconductor integrated circuit, and a semiconductor integrated circuit.

### BACKGROUND

With the advent of very small sub-micron CMOS transistors, recent semiconductor integrated circuits have lower power supply voltages and lower threshold voltages, have thinner gate oxide films, and have higher leakage currents. For example, the power consumption by switching and the power consumption by a leakage current are substantially the same in a 40-nm design rule CMOS transistor circuit. A process of reducing power consumption by gating a clock of a flip-flop like clock gating and reducing switching of a transistor alone is insufficient to reduce power consumption of a whole of a CMOS transistor circuit. A technique for reducing the power consumption by a leakage current plays a significant role.

Techniques for reducing the power consumption by a leakage current include a powerful one involving turning off power to a circuit not in operation during standby. However, it is necessary for a CPU, a controller, or a circuit configured to process a stream of data to return a state of the circuit to an original state prior to power-off and immediately restart processing when the power to the circuit is turned back to on. There are several methods available for turning power back to on.

A first one of the methods is to turn off power to a whole of a target circuit and, when the power is turned back to on, restart from a reset sequence. A second one is to save a value of a register on an external SRAM, power to which is on, using a scan chain before the power is turned off and, when the power is turned back to on, reload the saved value into the register using the scan chain. A third one is a method using a retention register including a general flip-flop and a retention flip-flop. The method using a retention register is to save a value of a general flip-flop on a retention flip-flop corresponding one-to-one to the general flip-flop when the power is turned off and reload the value from the retention flip-flop into the general flip-flop when the power is turned back to on.

However, the method using a retention register involves turning on a retention power supply on standby when the power is turned off and holding a value of a general flip-flop in a retention flip-flop. A retention register needs to include a general flip-flop and a retention flip-flop, and a circuit size of a retention register is about twice a circuit size of a general register including only a general flip-flop. Accordingly, replacement of all registers with retention registers increases a circuit size.

Under the circumstances, designers have analyzed a block diagram of a hardware circuit or a register transfer level (RTL) description in a hardware description language (HDL) and have manually selected which register is to be replaced with a retention register.

However, a semiconductor integrated circuit includes, e.g., several thousand registers. If a designer manually determines which register is to be replaced with a retention register, the designer cannot minimize the total size, i.e., the number of retention registers.

### BRIEF DESCRIPTION OF THE DRAWINGS

FIG. 1 is a view showing a configuration of an information processing system according to a first embodiment;

FIG. 2 is a diagram showing a configuration of a design apparatus according to the first embodiment;

FIG. 3 is a view showing an example of a behavioral description in SystemC;

FIG. 4 is a diagram showing an example of a CDFG generated by a CDFG generator;

FIG. 5 is a diagram showing an example of a CDFG after scheduling;

FIG. 6 is a diagram showing an example of a data path circuit generated by a binder;

FIG. 7 is a diagram showing an example of a control circuit generated by a control circuit generator;

FIG. 8 is a diagram showing an example of a control circuit generated by a sleep state transition controlling circuit generator;

FIG. 9 is a view showing an example of low power consumption information generated by a low power consumption information generator;

FIG. 10 is a view showing an example of an RTL description generated by an RTL description generator;

FIG. 11 is a flow chart showing an example of a flow of a design process for a design apparatus;

FIG. 12 is a block diagram showing a configuration of a semiconductor integrated circuit according to a second embodiment; and

FIG. 13 is a partial enlarged view showing registers and a portion involved in power supply control of a data path circuit on an enlarged scale.

### DETAILED DESCRIPTION

A design apparatus according to the present embodiments includes a CDFG generator, a scheduler, a binder, a retention register selector, a control circuit generator, and an RTL description generator. The binder generates a data path circuit in which hardware elements are allocated to a CDFG after scheduling by the scheduler. The retention register selector detects, as a retention control step, a control step with a minimum number of latch bits from a CDFG after scheduling and selects, as a retention register, a register allocated to the detected retention control step. The control circuit generator generates a control circuit configured to perform an execution control of the data path circuit and to cause a state of the data path circuit to transition to the retention control step when a signal for power-off is enabled.

Embodiments of the present invention will be described below in detail with reference to the drawings.

### First Embodiment

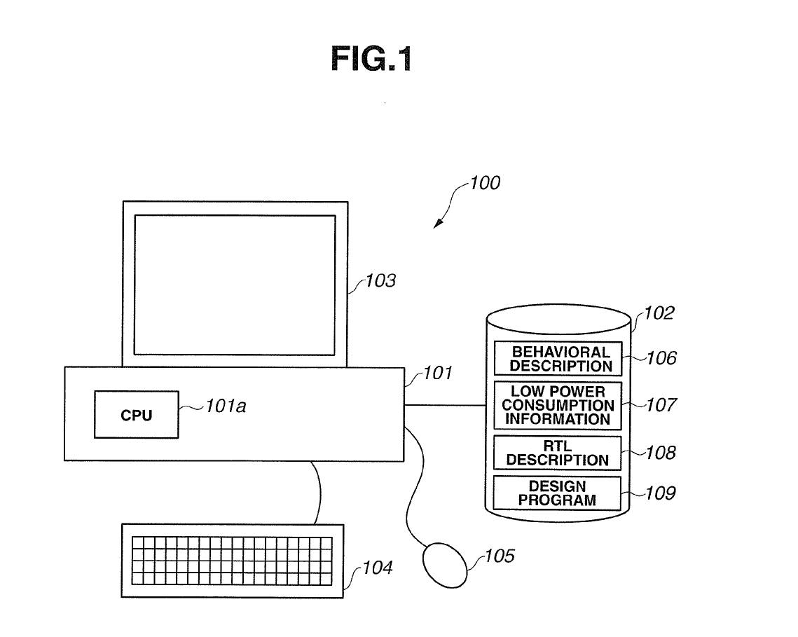

A configuration of an information processing system according to a first embodiment will be described first with reference to FIG. 1.

FIG. 1 is a view showing the configuration of the information processing system according to the first embodiment.

As shown in FIG. 1, an information processing system 100 includes a main unit 101, a storage device 102 configured to store various types of data, and a display device 103 configured to display various types of data. The main unit 101 is a main body of computer equipment such as a personal computer and is provided with a CPU 101a, a main memory (not shown), and the like. The main unit 101 is connected to a keyboard 104 and a mouse 105 as input devices. The main unit 101 executes various programs in accordance with instructions from the input devices.

The storage device 102 stores a behavioral description 106 in the C language, SystemC, or the like, low power consumption information 107 and an RTL description 108 which are generated from the behavioral description 106, and a design program 109 which includes a program having a function of generating the low power consumption information 107 and the RTL description 108 from the behavioral description 106.

A user can obtain the low power consumption information 107 and the RTL description 108 by using the keyboard 104 and the mouse 105 to run the design program 109 on the main unit 101 with the behavioral description 106 in the C language, SystemC, or the like as an input. As described above, the main unit 101 capable of executing the design program 109 constitutes a design apparatus 1 (to be described later) according to the present embodiment. Note that although the behavioral description 106, the low power consumption information 107, and the RTL description 108 are stored in the storage device 102, the pieces of data may be stored in another storage medium.

A configuration of the design apparatus 1 with the above-described configuration will be described.

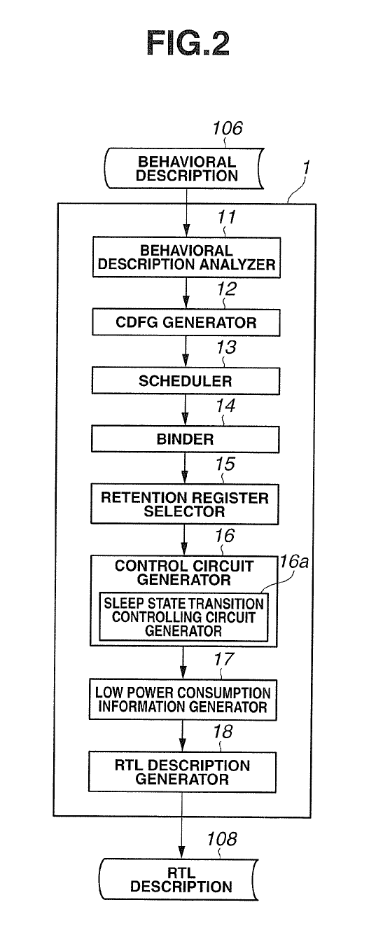

FIG. 2 is a diagram showing the configuration of the design apparatus according to the first embodiment.

As shown in FIG. 2, the design apparatus I includes a behavioral description analyzer 11, a control data flow graph (hereinafter referred to as a CDFG) generator 12, a scheduler 13, a binder 14, a retention register selector 15, a control circuit generator 16, a low power consumption information generator 17, and an RTL description generator 18. In the present embodiment, the control circuit generator 16 includes a sleep state transition controlling circuit generator 16a.

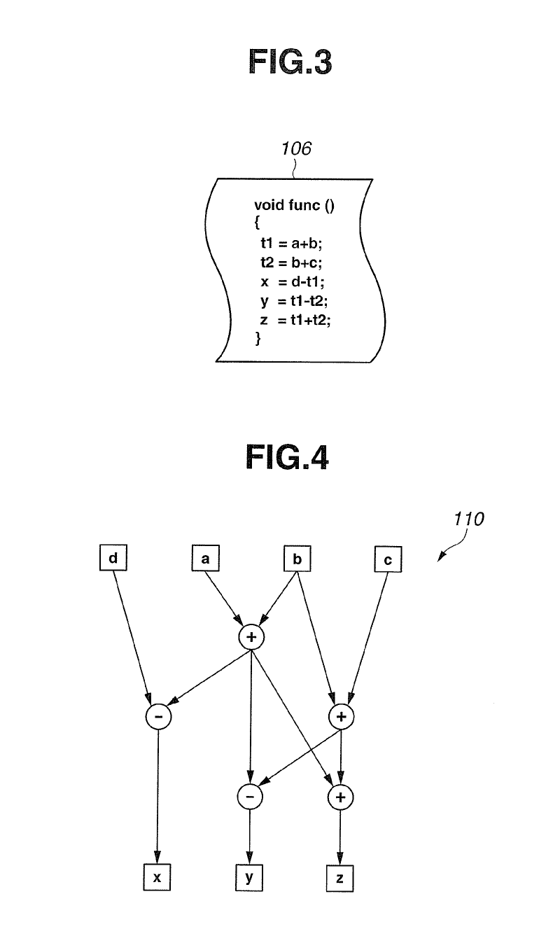

FIG. 3 is a view showing an example of a behavioral description in SystemC.

The behavioral description 106 in, for example, SystemC shown in FIG. 3 is inputted to the behavioral description analyzer 11. The behavioral description analyzer 11 reads the behavioral description 106 in SystemC, performs description analysis to check whether the behavioral description 106 is erroneous as a description in SystemC, analyzes whether high-level synthesis of the behavioral description 106 is possible, and converts the behavioral description 106 into a representation in an internal expression form of the design apparatus 1. The representation in the internal expression form of the design apparatus 1 (hereinafter referred to as an internal representation) obtained after the conversion is temporarily stored in a predetermined file format in the main memory (not shown) or the storage device 102.

The CDFG generator 12 reads control using a conditional statement such as an if statement or a switch statement and control using a loop statement such as a for statement, a while statement, or a do-while statement, analyzes an arithmetical operation, a comparison operation, a logical operation, and an assignment statement, and generates a CDFG.

FIG. 4 is a diagram showing an example of a CDFG generated by the CDFG generator.

In the example shown in FIG. 4, a CDFG 110, reference characters a to d denote input terminals, and reference characters x to z denote output terminals. The CDFG 110 is a data flow graph in which an operator serves as a node, and edges provide a connection between each of the input terminals a to d and an operator, a connection between an operator and an operator, and a connection between an operator and each of the output terminals x to z. Note that since a description of a control graph is unnecessary in the present embodiment, a control graph is omitted in FIG. 4. Information on the CDFG 110 is temporarily stored as an internal representation of the design apparatus 1 in the predetermined file format in the main memory or the storage device 102.

The scheduler 13 takes in the CDFG 110 and performs scheduling to determine in which step each operation in the CDFG 110 is to be performed. Such steps are referred to as control steps here.

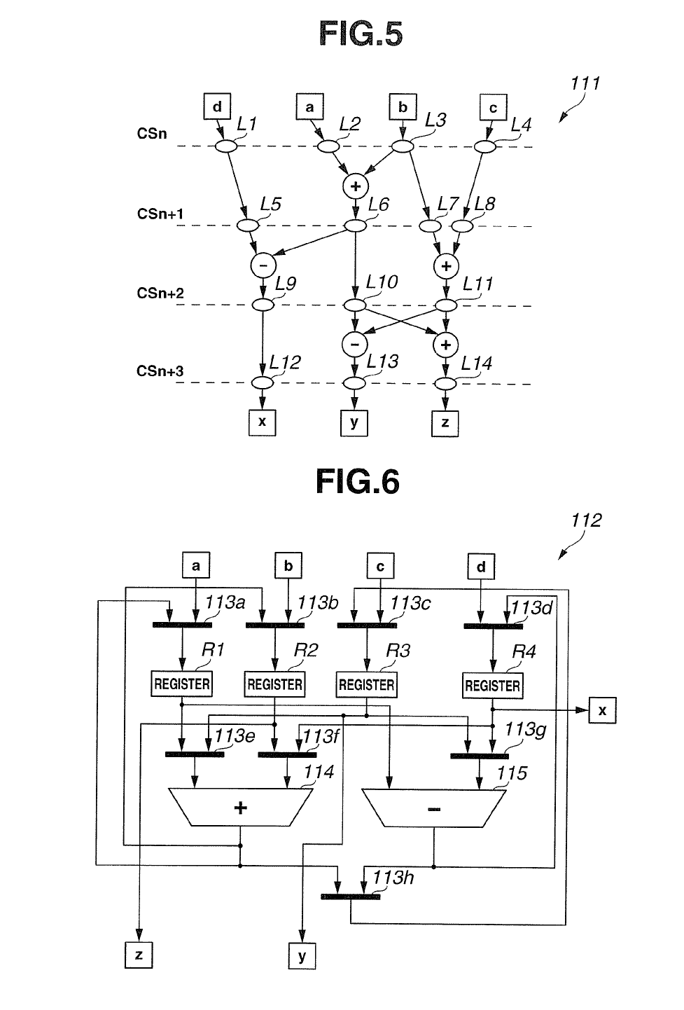

FIG. 5 is a diagram showing an example of a CDFG after scheduling. In a CDFG 111 after scheduling shown in FIG. 5, an area between a broken line and a broken line indicates a control step. The CDFG 111 has control steps CSn to CSn+3.

The control steps CSn to CSn+3 each represent a behavior in one cycle of a clock signal, and a latch is required to pass data between control steps. For the reason, the CDFG 111 has latches L1 to L14, as shown in FIG. 5. Note that since hardware elements are not allocated to the CDFG 111, the components L1 to L14 are called not registers corresponding to hardware elements but latches. Information on the CDFG 111 after scheduling is also temporarily stored as an internal representation of the design apparatus 1 in the predetermined file format in the main memory or the storage device 102.

The binder 14 allocates hardware elements to the CDFG 111 after scheduling and generates a data path circuit using a functional unit such as an adder or a subtracter, a multiplexer, a register, and the like.

FIG. 6 is a diagram showing an example of a data path circuit generated by the binder. As shown in FIG. 6, a data path circuit 112 includes a plurality of multiplexers (hereinafter referred to as MUXs) 113a to 113h, registers R1 to R4, an adder 114, and a subtracter 115.

The binder 14 holds correspondence relationship information indicating to which one of the registers R1 to R4 each of the latches L1 to L14 of the control steps CSn to CSn+3 is allocated when hardware elements are allocated to the CDFG 111 after scheduling. The correspondence relationship information and information on the data path circuit 112 are also temporarily stored as internal representations of the design apparatus 1 in the predetermined file format in the main memory or the storage device 102.

The retention register selector 15 detects a control step whose latches required between the control step and a next control step after scheduling have a minimum total number of bits.

The retention register selector 15 calculates the number of bits of required latches in order from the control step CSn. In the present embodiment, assume that pieces of data inputted through the input terminals a to d are 16 bits long and that a piece of data obtained after an addition and a piece of data obtained after a subtraction are also 16 bits long. Since the control step CSn requires 4 latches, i.e., the latches L1 to L4 as latches configured to hold 16 bits of data, the number of bits of latches required by the control step CSn is 64. Similarly, the number of bits of latches required by the control step CSn+1 is 64, the number of bits of latches required by the control step CSn+2 is 48, and the number of bits of latches required by the control step CSn+3 is 48.

Accordingly, the control steps CSn+2 and CSn+3 are control steps, latches of each of which have a minimum total number of bits, and are control steps as candidates for retention.

If there are a plurality of control steps, latches of each of which have a minimum total number of bits, as described above, the retention register selector 15 detects one of the control steps which has a smallest step number as a retention control step serving as a retention target. For the reason, in the present embodiment, the retention register selector 15 detects the control step CSn+2 as a retention control step. Note that although the control step with the smallest step number is detected as a retention control step in the present embodiment, the present invention is not limited to this. A control step with a second smallest step number or any other control step may be detected as a retention control step as long as latches of the control step have a minimum total number of bits.

The retention register selector 15 detects, on the basis of the correspondence relationship information generated by the binder 14, to which register of the data path circuit 112 each of the latches L9 to L11 of the control step CSn+2 corresponds. In the examples shown in FIGS. 5 and 6, the latch L9 of the control step CSn+2 corresponds to the register R4 of the data path circuit 112; the latch L10, the register R1; and the latch L11, the register R2. Accordingly, the retention register selector 15 selects the registers R1, R2, and R4 as retention registers.

It can be seen from this that, in the control step CSn+2 serving as a retention control step, only the registers R1, R2, and R4 hold significant values and that a value of the register R3 is not referred to. For the reason, in a state corresponding to the control step CSn+2 (hereinafter also referred to as a retention state RS), only the values of the registers R1, R2, and R4 need to be held when power is turned off.

The control circuit generator 16 generates a control circuit for performing operations in the data path circuit 112 as in the control steps.

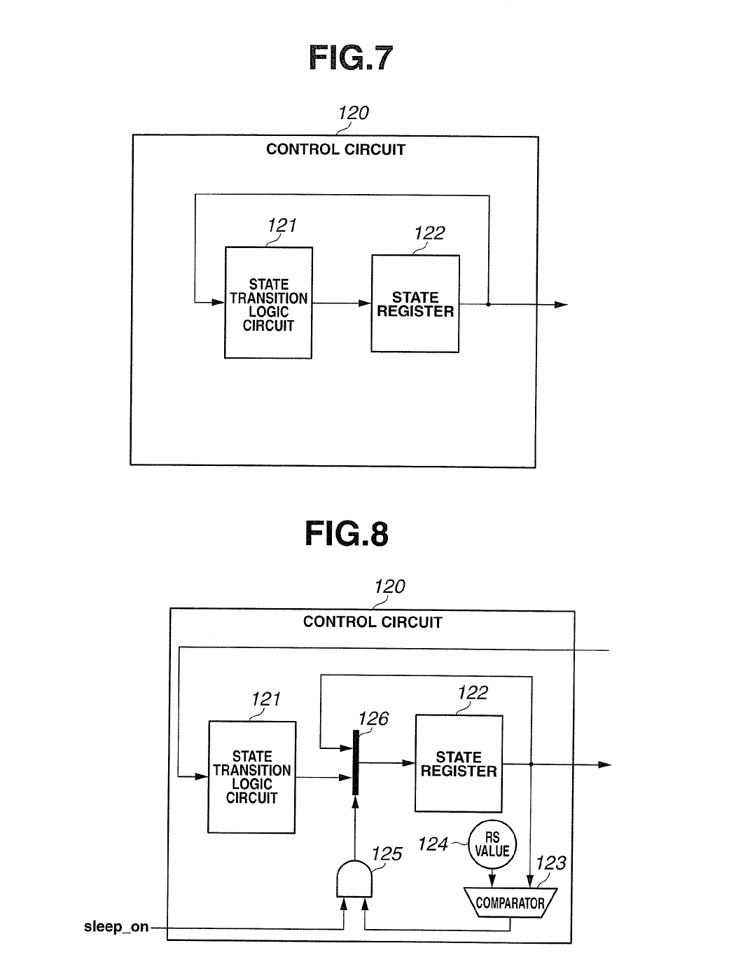

FIG. 7 is a diagram showing an example of a control circuit generated by the control circuit generator.

A control circuit 120 shown in FIG. 7 is a finite state machine (FSM)and includes a state transition logic circuit 121 and a state register 122.

The state transition logic circuit 121 outputs a control signal for transitioning from a certain state to a next state to the state register 122. The state register 122 takes in the control signal on a leading edge of a clock signal and outputs the control signal to the multiplexers 113a to 113h of the data path circuit 112. The multiplexers 113a to 113h of the data path circuit 112 are controlled on the basis of the control signal from the state register 122. For example, predetermined data paths are selected, e.g., between the input terminal a and the register R1 and between the register R1 and the adder 114.

The sleep state transition controlling circuit generator 16a generates a circuit configured to cause astute of the data path circuit 112 to transition from a certain state in operation to the retention state RS On the present embodiment, a state indicating the retention control step CSn+2) while a sleep signal (sleep_on) for power-off inputted from outside the control circuit 120 is enabled (1 in the present embodiment). The sleep state transition controlling circuit generator 16a adds the generated circuit to the control circuit 120 for normal operation generated by the control circuit generator 16 and generates the final control circuit 120.

FIG. 8 is a diagram showing an example of a control circuit generated by the sleep state transition controlling circuit generator.

The control circuit 120 includes a comparator 123, a retention state value 124, an AND gate 125, and a MUX 126, in addition to the state transition logic circuit 121 and the state register 122.

A control signal from the state register 122 is supplied to one terminal of the comparator 123. The retention state value 124 corresponding to the retention state RS is supplied to the other terminal of the comparator 123. The comparator 123 compares the control signal with the retention state value 124 and, if the values coincide, outputs “1” to one terminal of the AND gate 125.

The sleep signal (sleep_on) is supplied to the other terminal of the AND gate 125. The AND gate 125 outputs “1” as a selection signal to the MUX 126 if the sleep signal (sleep_on) is “1” and enabled, and a value of the state register 122 coincides with the retention state value 124, i.e., the comparator 123 outputs “1.” The AND gate 125 outputs “0” as the selection signal to the MUX 126 if the sleep signal (sleep_on) is “0” and disabled or if the value of the state register 122 does not coincide with the retention state value 124, i.e., the comparator 123 outputs “0.”

The control signal from the state transition logic circuit 121 and a feedback signal from the state register 122 are inputted to the MUX 126. The MUX 126 selects the control signal from the state transition logic circuit 121 and outputs the control signal to the state register 122 if the selection signal is “0” and selects the feedback signal from the state register 122 and outputs the feedback signal to the state register 122 if the selection signal is “1.”

As described above, the control circuit 120 is a circuit configured to cause the state to transition when the sleep signal (sleep_on) is enabled, and the state is not the retention state RS and to hold data outputted from the state register 122 when the sleep signal (sleep_on) is enabled, and the state transitions to the retention state RS. Note that information on the control circuit 120 is also temporarily stored as an internal representation of the design apparatus 1 in the predetermined file format in the main memory or the storage device 102.

The low power consumption information generator 17 generates, as the low power consumption information 107 serving as a retention target, information on a power source and aground, information on the registers R1, R2, and R4 selected as retention registers, and information on the state register 122 when the state is the retention state RS that is generated by the control circuit generator 16.

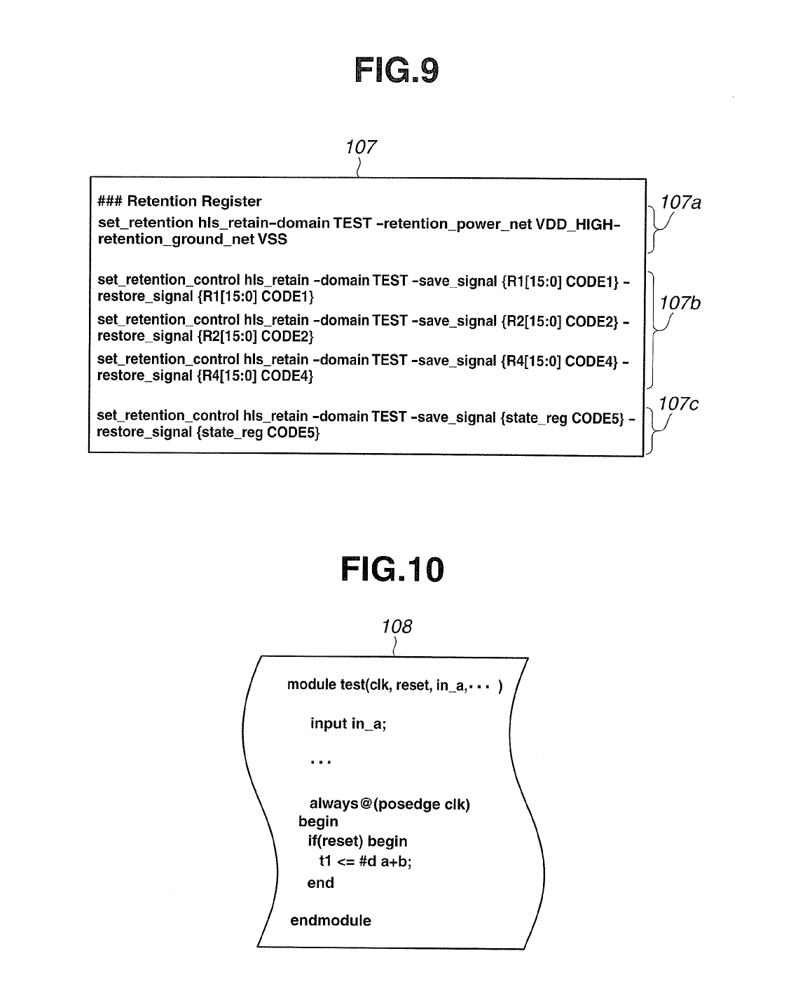

FIG. 9 is a view showing an example of low power consumption information generated by the low power consumption information generator. As shown in FIG. 9, information 107a on the power source and the ground, information 107b on the registers R1, R2, and R4 selected as retention registers, and information 107c on the state register 122 when the state is the retention state RS are stored in the low power consumption information 107. The low power consumption information 107 is stored in a predetermined file format in the storage device 102.

The RTL description generator 18 generates the RTL description 108 in Verilog or VHDL on the basis of the information on the generated data path circuit 112 and the information on the generated control circuit 120.

FIG. 10 is a view showing an example of an RTL description generated by the RTL description generator. The RTL description 108 is stored in a predetermined file format in the storage device 102.

A design process in the design apparatus 1 with the above-described configuration will be described.

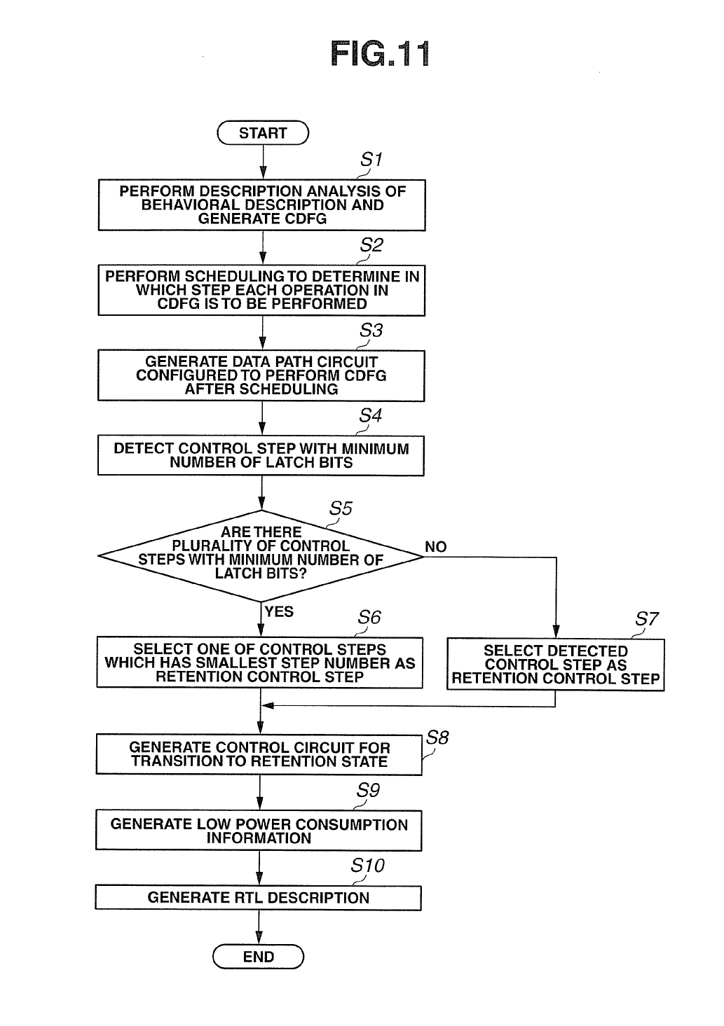

FIG. 11 is a flow chart showing an example of a flow of the design process in the design apparatus.

First, description analysis of the behavioral description 106 is performed, and the CDFG 110 is generated (step S1). Scheduling is performed to determine in which step each operation in the CDFG 110 is performed (step S2), and the data path circuit 112 configured to perform the CDFG 111 after the scheduling is generated (step S3). A control step with a minimum number of latch bits is detected (S4). It is determined whether there are a plurality of control steps with the minimum number of latch bits (step S5). If there are a plurality of control steps with the minimum number of latch bits, a result of the determination in step 85 is YES, and one of the control steps which has a smallest step number is selected as a retention control step (S6). If there is only one control step with the minimum number of latch bits, the result of the determination in step S5 is NO, and the detected control step is selected as the retention control step (step S7). The control circuit 120 for transition to the retention state is generated (step S8), and the low power consumption information 107 is generated (step S9). Finally, the RTL description 108 is generated (step S10), and the process ends.

As described above, the design apparatus 1 selects registers serving as retention targets by the retention register selector 15 so as to minimize the total number of bits of retention registers, i.e., the number of retention registers. Since the design apparatus 1 automatically selects registers serving as retention targets so as to minimize the total number of bits of retention registers, the total size of retention registers can be minimized.

Accordingly, a design apparatus according to the present embodiment can easily minimize the total size of retention registers.

Conventionally, designers have manually selected which register is to be set as a retention register. Designers need to repeatedly verify whether retention registers are correctly selected and whether a desired behavior is performed when power is turned off and when the power is turned back to on while repeating RTL simulation, which increases a design verification period.

In contrast, the design apparatus 1 according to the present embodiment automatically selects registers serving as retention targets so as to minimize the total number of bits of retention registers. The design apparatus 1 can make a design verification period shorter than ever before.

### Second Embodiment

A second embodiment will be described.

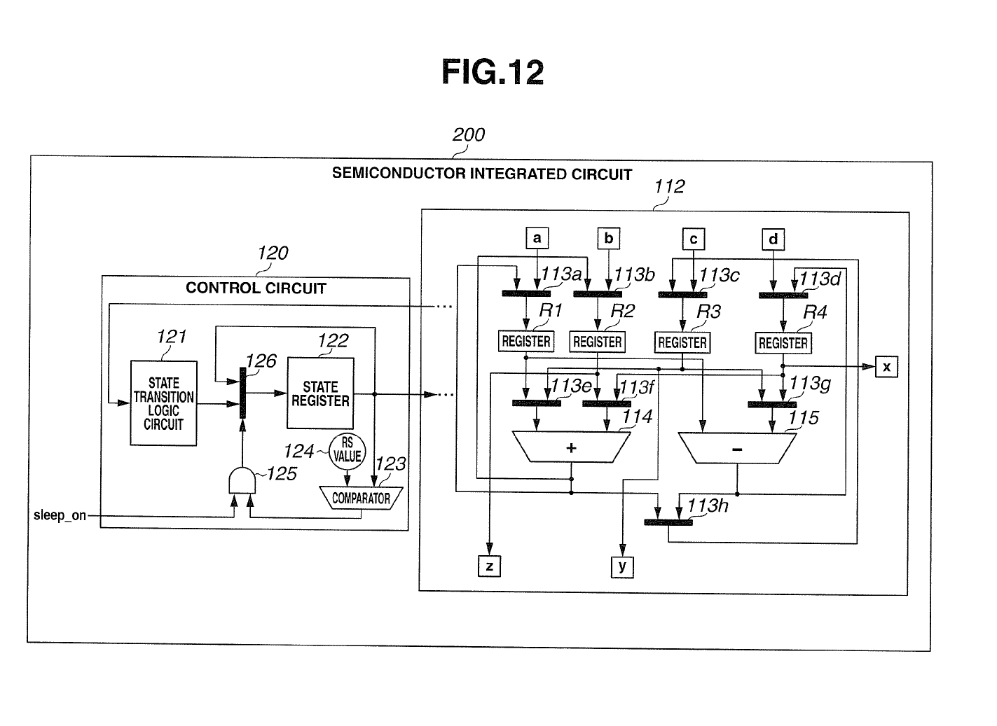

FIG. 12 is a block diagram showing a configuration of a semiconductor integrated circuit according to the second embodiment. Note that same components in FIG. 12 as the components in FIGS. 6 and 8 are denoted by same reference numerals, and a description of the components will be omitted.

A semiconductor integrated circuit 200 in FIG. 12 is a circuit obtained by performing logic synthesis of the low power consumption information 107 and the RTL description 108 according to the first embodiment by a logic synthesis device (not shown) and includes a data path circuit 112 and a control circuit 120.

The data path circuit 112 and the control circuit 120 have same configurations as the configurations of the data path circuit 112 and the control circuit 120 according to the first embodiment. The control circuit 120 is a circuit configured to cause a state of the data path circuit 112 performing predetermined processing to transition to a retention state RS when a sleep signal (sleep_on) is enabled and to hold data outputted from a state register 122 when the data path circuit 112 transitions to the retention state RS.

Control of power to registers R1 to R4 when power is turned off and when the power is turned back to on will be described.

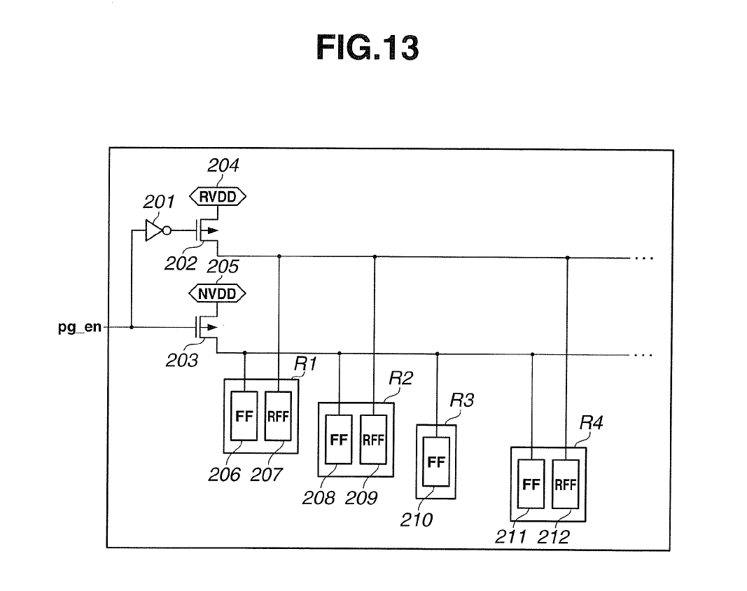

FIG. 13 is a partial enlarged view showing registers and a portion involved in the power supply controller configured to control the power to the registers of the data path circuit on an enlarged scale.

The power supply controller shown in FIG. 13 includes an inverter 201, P-type MOS transistors 202 and 203, an RVDD 204 which is a power source during retention, an NVDD 205 which is a power source in normal times, and the registers R1 to R4.

As described above, in the present embodiment, the registers R1, R2, and R4 serve as retention registers. For the reason, the registers R1, R2, and R4 respectively include flip-flops (hereinafter referred to as FFs) 206, 208, and 211 configured to hold data in normal times and retention FFs 207, 209, and 212 configured to hold data during retention. The register R3 is a general register and includes an FF 210 configured to hold data in normal times.

In normal times, “0” is supplied as a power supply controlling signal (pg_en) to a gate of the P-type MOS transistor 203, and the power supply controlling signal (pg_en) inverted by the inverter 201 is supplied to a gate of the P-type MOS transistor 202. This turns off the P-type MOS transistor 202a and turns on the P-type MOS transistor 203. As a result, power from the NVDD 205 serving as the power source in normal times is supplied to the FFs 206, 208, 210, and 211.

When the data path circuit 112 transitions to the retention state RS under control of the control circuit 120 at the time of power-off, pieces of data held by the FFs 206, 208, and 211 are loaded into the retention FFs 207, 209, and 212, respectively. When the data path circuit 112 transitions to the retention state RS under control of the control circuit 120 at the time of power-off, the power supply controlling signal (pg_en) switches from “0” to “1.” This turns on the P-type MOS transistor 202 and turns off the P-type MOS transistor 203. As a result, power is supplied from the RVDD 204 serving as the power source during retention to the retention FFs 207, 209, and 212. With the configuration, the retention FFs 207, 209, and 212 can hold the pieces of data held by the FFs 206, 208, and 211, respectively, when the power is turned off.

When the power is turned back to on, the pieces of data held by the retention FFs 207, 209, and 212 are reloaded into the FFs 206, 208, and 211, respectively, and the power supply controlling signal (pg_en) switches from “1” to “0.” This turns off the P-type MOS transistor 202 and turns on the P-type MOS transistor 203. As a result, the FFs 206, 208, and 211 can hold the pieces of data held by the retention FFs 207, 209, and 212, respectively, when the power is turned off and can return to a state before the power is turned off.

Conventionally, designers have manually selected which register is to be set as a retention register and have had difficulty in minimizing a total size of retention registers of a semiconductor integrated circuit.

In contrast, the semiconductor integrated circuit 200 according to the present embodiment is generated from an RTL description 108 which is automatically designed so as to minimize a total size of retention registers. Accordingly, the semiconductor integrated circuit 200 can have a smaller circuit size than a circuit size of a conventional semiconductor integrated circuit.

Additionally, since the total size of retention registers can be reduced in the semiconductor integrated circuit 200, the power consumption by a leakage current at the time of power-off can be reduced, compared to a conventional semiconductor integrated circuit.

Note that all or part of a design program that performs the above-described behaviors is recorded or stored as a computer program product on a portable medium such as a flexible disk or a CD-ROM or a storage medium such as a hard disk. The program is read by a computer, and all or part of the behaviors is performed by the computer. Alternatively, all or part of the program can be distributed or provided over a communication network. A user can readily implement design apparatuses according to the present embodiments by downloading the program over the communication network and installing the program on a computer or installing the program on a computer from a recording medium.

The order of execution of the steps of the flow chart in the specification may be changed, a plurality of the steps may be simultaneously executed, or the steps may be executed in a different order each time unless such changes are inconsistent with the nature of the invention.

The present invention is not limited to the above-described embodiments, and various changes, modifications, and the like can be made without departing from the spirit and scope of the present invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An apparatus for designing a semiconductor integrated circuit, the apparatus comprising:
a control data flow graph generator configured to generate a control data flow graph based on a result of a description analysis of a behavioral description;
a scheduler configured to schedule a plurality of control steps associated with operations in the control data flow graph;
a binder configured to generate a data path circuit in which a hardware element is allocated to the control data flow graph after scheduling;
a retention register selector configured to detect, as a retention control step, one of the control steps which has a minimum number of latch bits from the control data flow graph after scheduling and to select, as a retention register, a register allocated to the detected retention control step;
a control circuit generator configured to generate a control circuit, which controls execution of the data path circuit, and to cause a state to transition to the retention control step when a signal for power-off is enabled; and
a Register Transfer Level (RTL) description generator configured to generate an RTL description based on information associated with the data path circuit generated by the binder and the control circuit generated by the control circuit generator.

2. The apparatus of claim 1, wherein, if there are a plurality of control steps which have the minimum number of latch bits among the control steps, the retention register selector is further configured to detect, as the retention control step, a control step of the plurality of control steps which has a smallest step number.

3. The apparatus of claim 1, further comprising a behavioral description analyzer configured to:
perform description analysis to check whether the behavioral description has any error;
analyze whether high-level synthesis of the behavioral description is possible; and
convert the behavioral description into a representation in an internal expression form of the apparatus.

4. The apparatus of claim 3, wherein the control data flow graph generator is further configured to generate the control data flow graph by:
reading control information using a conditional statement and a loop statement from the representation in the internal expression form obtained through the conversion by the behavioral description analyzer; and
analyzing an operation and an assignment statement.

5. The apparatus of claim 1, further comprising a low power consumption information generator configured to generate, as low power consumption information:
information on a power source and a ground;
information on the register selected as the retention register; and
information on a state register when the state is a state corresponding to the retention control step.

6. The apparatus of claim 1, wherein each of the plurality of control steps has a plurality of latches for passing data.

7. The apparatus of claim 6, wherein the hardware element allocated to the control data flow graph comprises at least one functional unit, at least one multiplexer, and at least one register.

8. The apparatus of claim 7, wherein the binder is further configured to hold correspondence relationship information indicating to which one of the at least one register each of the plurality of latches of the plurality of control steps is allocated.

9. The apparatus of claim 8, wherein the retention register selector is further configured to select the register allocated to the retention control step as the retention register based on the correspondence relationship information.

10. A method for designing a semiconductor integrated circuit, the method comprising:
generating a control data flow graph based on a result of a description analysis of a behavioral description;
scheduling a plurality of control steps associated with operations in the control data flow graph;
generating a data path circuit in which a hardware element is allocated to the control data flow graph after scheduling;
detecting, as a retention control step, one of the control steps which has a minimum number of latch bits from the control data flow graph after scheduling and selecting, as a retention register, a register allocated to the detected retention control step;
generating a control circuit which controls execution of the data path circuit and causes a state to transition to the retention control step when a signal for power-off is enabled; and
generating a Register Transfer Level (RTL) description based on information associated with the generated data path circuit and the generated control circuit.

11. The method of claim 10, further comprising determining, as the retention control step, a control step of a plurality of control steps associated with a smallest step number, in response to determining that there are a plurality of control steps associated with the minimum number of latch bits among the control steps.

12. The method of claim 10, further comprising:
performing a description analysis to determine whether the behavioral description has any error;
analyzing whether high-level synthesis of the behavioral description is possible; and
converting the behavioral description into a representation in an internal expression form of a design apparatus for the semiconductor integrated circuit.

13. The method of claim 12, further comprising
generating the control data flow graph by reading control information using a conditional statement and a loop statement from the representation in the internal expression form obtained through the conversion; and
analyzing an operation and an assignment statement.

14. The method of claim 10, further comprising generating, as low power consumption information:
information on a power source and a ground;
information on the register selected as the retention register; and
information on a state register when the state is a state corresponding to the retention control step.

15. The method of claim 10, wherein each of the plurality of control steps has a plurality of latches for passing data.

16. The method of claim 15, wherein the hardware element allocated to the control data flow graph comprises at least one functional unit, at least one multiplexer, and at least one register.

17. The method of claim 16, further comprising holding correspondence relationship information indicating to which one of the at least one register each of the plurality of latches of the plurality of control steps is allocated.

18. The method of claim 17, further comprising selecting the register allocated to the retention control step as the retention register on the basis of the correspondence relationship information.

19. A semiconductor integrated circuit comprising:
a data path circuit configured to perform predetermined processing; and
a control circuit including a state register which outputs data for transition of a state of the data path circuit, the control circuit configured to:
cause the state of the data path circuit to transition to a retention state when a signal for power-off is enabled; and
hold data outputted from the state register when the state of the data path circuit transitions to the retention state.

20. The semiconductor integrated circuit of claim 9, wherein the control circuit is further configured to:
hold a retention state value corresponding to the retention state;
compare the data outputted from the state register with the retention state value; and
if the data coincides with the retention state value, hold the data outputted from the state register.
